(19) United States
(12) Patent Application Publication
(10) Pub. No.: US 2020/0178399 A1
(43) Pub. Date: Jun. 4, 2020

(54) METHOD FOR FORMING MULTILAYERED CIRCUIT PATTERN ON SURFACE OF THREE-DIMENSIONAL METAL BOARD

(71) Applicant: MDM Inc., Daegu (KR)

(72) Inventor: Ku Yong Kim, Yangsan-si, Gyeongsangnam-do (KR)

(21) Appl. No.: 16/697,182

(22) Filed: Nov. 27, 2019

(30) Foreign Application Priority Data
Dec. 4, 2018 (KR) 10-2018-0154636

(51) Int. Cl. H05K 3/46; H05K 3/14; H05K 3/12

(52) U.S. Cl. CPC H05K 3/4608; H05K 3/143; H05K 3/465; H05K 3/1275; H05K 3/4664; H05K 3/1225

(57) ABSTRACT

A method for forming a multilayered circuit pattern on a surface of a 3D metal board includes: forming a first insulation layer on the surface of the 3D metal board; forming a first conductive pattern on the first insulation layer; forming a second insulation layer on the first conductive pattern except for a predetermined region; forming a second conductive pattern on the second insulation layer; and forming a third insulation layer on the second conductive pattern except for one or more circuit element mounting regions.

### CROSS-REFERENCE TO RELATED APPLICATIONS

This application is based on and claims priority under 35 U.S.C. § 119 to Korean Patent Application No. 10-2018-0154636 filed on Dec. 4, 2018, in the Korean Intellectual Property Office, the disclosure of which is herein incorporated by reference in its entirety.

### BACKGROUND

### 1. Field

The present disclosure relates to a method for forming an electronic circuit pattern on a metal board, and more particularly, to a method for forming a circuit pattern, which can directly form a circuit pattern on a surface of a three-dimensional (3D) metal board having a curve formed on the surface.

### 2. Description of the Related Art

Currently, single-layered and multilayered printed circuit boards (PCBs) are widely used as boards for semiconductor package. As functions of electronic devices or electric products are enhanced, wires on PCBs increase and high-density components are mounted on the PCBs. Therefore, the PCBs have been developed into multilayered and high-integrated structures, and a problem of radiating heat is arising as the most urgent issue to be solved.

To overcome the problem of such a related-art PCB, metal cores having high thermal conductivity are increasingly used as a metal substrate, and a single-layered or multilayered circuit pattern is formed on the metal substrate.

However, if the metal substrate should be bent or should be formed in a 3D shape due to a structural feature of an electronic device on which the metal substrate is to be mounted, it is not easy to form a circuit pattern on the metal substrate. Thus, there is a method of dividing the metal substrate into a plurality of flat substrates and forming a circuit pattern thereon. For example, referring to FIG. 1, if a structure 1 of an electronic device is a 3D-shaped metal board having stepped portions on a surface, it is common that a plurality of metal substrates 3 are installed on the metal board 1 and circuit patterns and circuit elements 100 are formed thereon.

However, since the metal substrate 3 should be divided into the plurality of metal substrates according to the shape of the metal board 1, there is a problem that the circuit elements or circuit patterns should be separately designed to suit the respective metal substrates and thus a complicated process is required to form a circuit.

### SUMMARY

The present disclosure has been developed in order to solve the above-described problems, and an object of the present disclosure is to provide a method for forming a multilayered circuit pattern, which can easily design a circuit pattern or a circuit element by directly forming a multilayered circuit pattern on a 3D metal board, and can achieve miniaturization of a device by reducing a volume of the device.

According to an embodiment of the present disclosure, a method for forming a multilayered circuit pattern on a surface of a 3D metal board includes: forming a first insulation layer on the surface of the 3D metal board; forming a first conductive pattern on the first insulation layer; forming a second insulation layer on the first conductive pattern except for a predetermined region; forming a second conductive pattern on the second insulation layer; and forming a third insulation layer on the second conductive pattern except for one or more circuit element mounting regions.

According to an embodiment of the present disclosure, a multilayered circuit pattern and a circuit element can be directly formed even on a D3 metal board having a curve formed on a surface thereof. Therefore, the circuit pattern can be simply designed. In addition, a pattern can be formed on a stepped portion of the 3D board and an element can be mounted thereon. Therefore, there is an effect that a device can be miniaturized.

### BRIEF DESCRIPTION OF THE DRAWINGS

The above and/or other aspects of the present disclosure will be more apparent by describing certain exemplary embodiments of the present disclosure with reference to the accompanying drawings, in which:

FIG. 1 is a view illustrating a related-art configuration in which a metal substrate is installed on a 3D structure;

FIGS. 2A and 2B are views illustrating examples of a multilayered circuit pattern formed on a 3D metal board according to an embodiment of the present disclosure;

FIG. 3 is a flowchart illustrating a method for forming a multilayered circuit pattern on a 3D metal board; and

FIGS. 4A, 4B, 4C, and 4D and 5A, 5B, 5C, and 5D are views illustrating steps for forming a multilayered circuit pattern according to an embodiment.

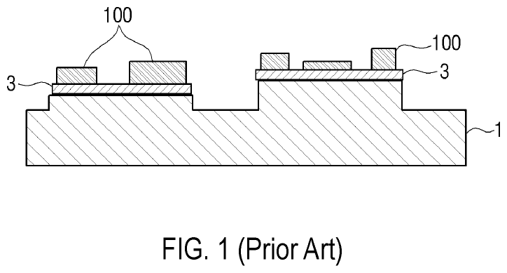

### DETAILED DESCRIPTION OF EMBODIMENTS

Exemplary embodiments will now be described more fully with reference to the accompanying drawings to clarify objects, other objects, features and advantages of the present disclosure. The exemplary embodiments may, however, be embodied in many different forms and should not be construed as limited to the exemplary embodiments set forth herein. Rather, the exemplary embodiments are provided so that this disclosure will be thorough and complete, and will fully convey the scope of the application to those of ordinary skill in the art.

In the drawings, dimensions of elements such as length, thickness, wideness, or the like are exaggerated for easy understanding of technical features.

As used herein, the singular forms are intended to include the plural forms as well, unless the context clearly indicates otherwise. It will be further understood that the terms “comprise” and/or “comprising,” when used in this specification, do not preclude the presence or addition of one or more other components.

Hereinafter, exemplary embodiments will be described in greater detail with reference to the accompanying drawings. The matters defined in the description, such as detailed construction and elements, are provided to assist in a comprehensive understanding of the exemplary embodiments. However, it is apparent that the exemplary embodiments can be carried out by those of ordinary skill in the art without those specifically defined matters. In the description of the exemplary embodiment, certain detailed explanations of related art are omitted when it is deemed that they may unnecessarily obscure the essence of the inventive concept.

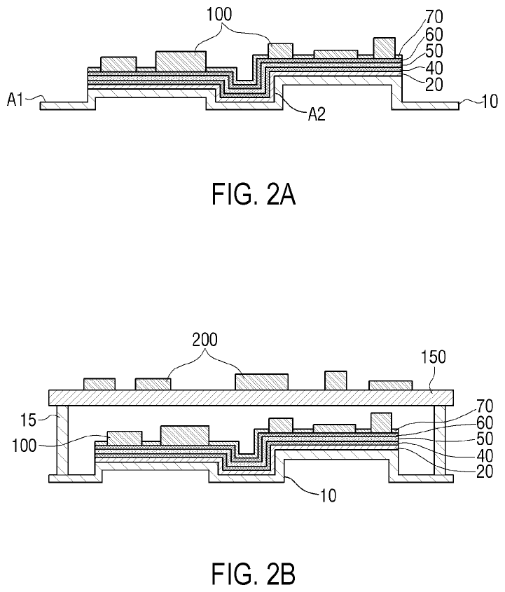

FIGS. 2A and 2B illustrate examples of a multilayered circuit pattern formed on a 3D metal board according to an embodiment of the present disclosure.

Referring to FIG. 2A, a multilayered circuit pattern according to an embodiment of the present disclosure is directly formed on a 3D metal board 10 and circuit elements are mounted thereon. In the present disclosure, the 3D metal board 10 refers to a metal board which has a 3D surface such as a curved surface or an inclined surface. However, the 3D metal board 10 of the present disclosure is not limited thereto, and includes, for example, a certain metallic member or a conductive structure having a 3D surface. In an embodiment, the 3D metal board 10 may be a certain structure forming a part of a certain electronic device or electronic component.

For example, the 3D metal board 10 may be a part of an inner surface of a case of a battery module, a heat sink, various home appliances or electronic products, or a part of an outer surface or an inner surface of a case of a component or a module disposed in an electronic product. That is, the 3D metal board 10 is not a structure that is originally intended to have a circuit pattern or a circuit element mounted thereon (that is, a circuit board), but a structure that is manufactured for other purposes, not for the purpose of a circuit board, like a case of an electronic device or a module (that is, a case protecting inner components and forming an exterior).

Typically, the case of such a device or component may be formed with a material having electrical conductivity and/or thermal conductivity, such as aluminum, and has a 3D shape including a curved surface or a stepped portion according to a purpose or function of the device or component. In an embodiment of the present disclosure, a multilayered circuit pattern according to the present disclosure can be formed on such a 3D metal board which is a part of an outer surface or an inner surface of a case of a device or component.

In an embodiment, a first insulation layer 20 may be formed on a region of the surface of the 3D metal board 10 where a circuit pattern is to be formed, and a first conductive circuit pattern 40, a second insulation layer 50, a second circuit pattern 60, and a third insulation layer 70 may be formed thereon in sequence, and then, a circuit element 100 may be mounted when necessary. The insulation layer and the circuit pattern may not be formed on some region of the surface of the 3D metal board 10 (for example, a region indicated by “A1”), and a circuit pattern may be formed on a stepped portion (for example, a side surface indicated by “A2”) of the 3D metal board 10, and a circuit element may be mounted on the stepped portion when necessary. That is, according to the present disclosure, all or some regions of the surface of the 3D metal board 10 may be used as a circuit board, regardless of whether the 3D metal board 10 has a curved surface or a stepped portion.

FIG. 2B illustrates another exemplary configuration in which a multilayered circuit pattern is formed on the 3D metal board 10 according to the present disclosure. In this embodiment, after a multilayered circuit pattern is formed on the 3D metal board 10 and the circuit element 100 is mounted thereon as shown in FIG. 2A, a board 150 such as a PCB and a circuit element 200 mounted on the board 150 are additionally installed on the 3D metal board 10. That is, one or more boards are additionally stacked on the 3D metal board 10 when necessary, such that a degree of integration of the circuit can be enhanced.

In this case, a support pole 15 may be extended from an upper surface of the metal board 10, and the board 150 may be coupled to an upper end of the support pole 15, thereby being disposed above the metal board 10. In an embodiment, a circuit pattern according to the present disclosure may also be formed on a side surface of the support pole 15, and various circuit elements 110 such as a temperature sensor, a humidity sensor, a light sensor, or the like may be mounted thereon when necessary.

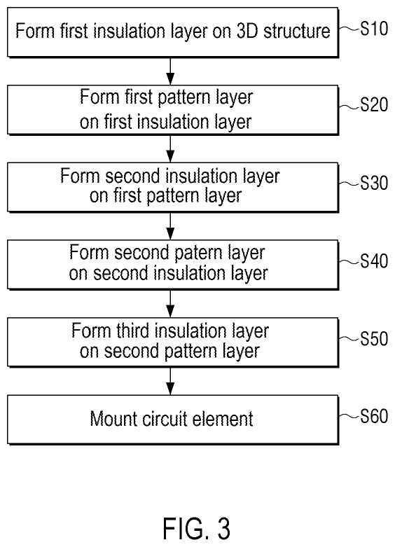

Hereinafter, a method for forming a multilayered circuit pattern on a 3D metal board will be described with reference to FIGS. 3 to 5D.

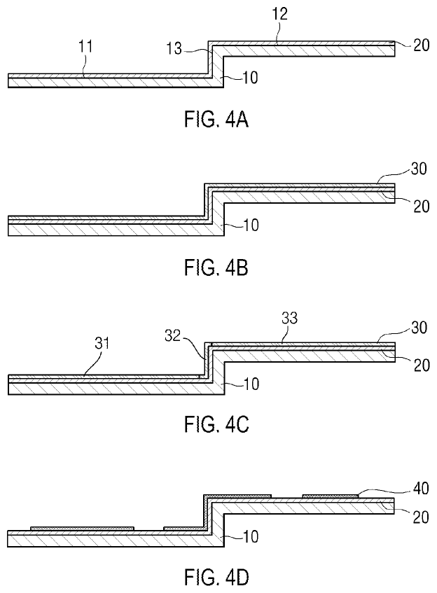

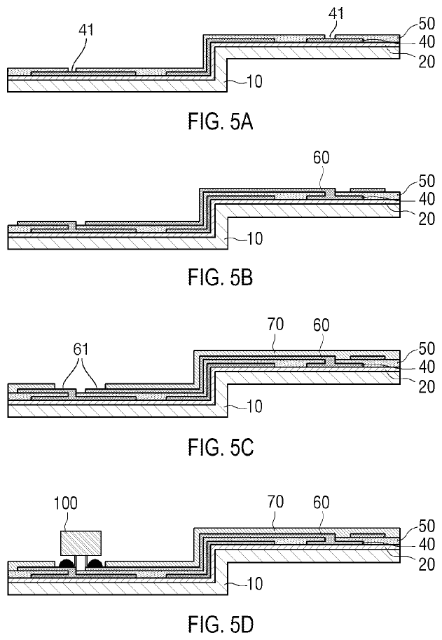

FIG. 3 is a flowchart of an exemplary method for forming a multilayered circuit pattern on a 3D metal board according to an embodiment, and FIGS. 4A, 4B, 4C′, and 4D, and FIGS. 5A, 5B, 5C, and 5D are views illustrating respective steps for forming the multilayered circuit pattern on the 3D metal board.

Referring to step S10 and FIG. 4A, a first insulation layer 20 is formed on an upper surface of a 3D metal board 10. The 3D metal board 10 may be a metal board having a 3D surface, or in an alternative embodiment, may be a part of an inner surface of a case of a home appliance or an electronic device, or a part of an outer surface or an inner surface of an electronic component or a module such as a battery module, a heat sink, or the like in a product or a device. The 3D metal board 10 may include a curved surface or a curved region. For convenience of explanation, FIG. 4A illustrates the 3D metal board 10 including flat portions 11, 12 which are different from each other in height, and a stepped portion 13 formed therebetween.

Since the 3D metal board 10 may be formed with a metallic material having electrical conductivity, such as aluminum or copper, the first insulation layer 20 is formed thereon to insulate from a circuit pattern. In an embodiment, insulating ink may be coated over the upper surface of the 3D metal board 10 by one of screening, spray coating, and solution immersion, or a combination of two or more of the above-mentioned methods. The insulating ink may use, for example, photo solder resist (PSR) ink, but is not limited thereto and a certain insulating liquid or an insulating material in a paste form, which are well known in the related-art, may be used.

The screening method includes a certain screening method, such as silk screening, paste screening, or the like. The spray coating is a method of spraying insulating ink to a region of the surface of the 3D metal board 10 where a circuit pattern is to be formed, by using a spray gun. The solution immersion method is a method of immersing the surface of the 3D metal board 10 in insulating ink contained in a container.

The method may further include a step of drying (curing) according to a type of insulating ink or paste, after forming the first insulation layer 20 by coating the 3D metal board with the insulating ink or paste. For example, when PSR insulating ink is used, a process of exposing the first insulation layer 20 to ultraviolet rays and then drying in hot air for a predetermined time may be added. Such an insulation layer coating method is well known in the related-art, and thus a detailed description thereof is omitted.

In an alternative embodiment, the insulation layer may be formed by attaching an insulation sheet to the surface of the 3D metal board 10. For example, when the first insulation layer 20 should be formed on a stepped portion of the 3D metal board 10, the first insulation layer 20 may be uniformly formed on the stepped portion by using the insulation sheet.

Next, referring to step S20 and FIGS. 4B and 4D, a first conductive circuit pattern 40 is formed on the first insulation layer 20. To achieve this, a first mask 30 perforated in the shape of a conductive pattern may be attached to the first insulation layer 20 as shown in FIG. 4B, and then, by coating conductive ink over the first mask 30 according to the shape of the conductive pattern by one of drawing, spray coating, and screening or a combination of two or more of these methods, the first circuit pattern 40 may be formed as shown in FIG. 4D.

In an embodiment, the first mask 30 may be a certain film such as a metallic film or a polymer resin film. The first mask 30 may already be bent or curved to have the same 3D shape as the 3D surface of the surface of the 3D metal board 10 that is to be masked. In addition, the first mask 30 may already be perforated according to the shape of the circuit pattern to be formed on the 3D metal board 10, and, at step S30, the first mask 30 is attached to the first insulation layer 20 of the 3D metal board. The first mask 30 may not be required to be attached to the entire surface of the 3D metal board 10 or the first insulation layer 20, and the first mask 30 may be attached only to a region of the surface of the 3D metal board 10 where the circuit pattern is to be formed.

FIG. 4C illustrates an alternative embodiment of the first mask 30. In this embodiment, the first mask 30 includes a plurality of sub masks 31, 32, 33 to cover different regions of the surface of the 3D metal board 10, respectively. For example, the plurality of sub masks may include a flat sub mask to cover a flat region of the 3D metal board 10, and a 3D sub mask to cover a stepped portion or a curved portion. In the illustrated embodiment, the first and third masks 31, 33 may be the flat sub masks to cover the flat portions of the surface of the 3D metal board, and the second sub mask 32 may be the 3D sub mask which is bent or curved to have the same 3D shape as the 3D surface of the 3D metal board.

Ends of the neighboring sub masks may be in close contact with each other, or may have regions overlapping each other, or may be spaced apart from each other by a predetermined distance.

When the mask is divided into the plurality of sub masks to separately cover the flat portions and the stepped portions of the surface of the 3D metal board, the first mask 30 can be attached to the first insulation layer 20 more easily than when one mask is attached to cover the entire surface of the 3D metal board.

After the first mask 30 is attached to the first insulation layer 20 as described above, conductive ink may be coated according to the shape of the conductive pattern of the first mask 30, and the first circuit pattern 40 may be formed by removing the first mask 30 as shown in FIG. 4D.

In an embodiment, the first circuit pattern 40 may be formed by coating with conductive ink in at least one method of drawing, spray coating, and screening.

In the present disclosure, the conductive ink includes conductive paste ink having relatively high viscosity, and conductive nano ink having relatively low viscosity. The conductive paste ink may be manufactured by mixing metallic powder (for example, silver powder) of hundreds of nanometers to a few micrometers with a polymer resin solution, various additives, and a functional solution, and may be used for printing in a screening method. The conductive nano ink may be a mixture of metal nano particles of a few nanometers to hundreds of nanometers with a dispersing agent and various additives, and may be used for various printing methods such as drawing or spray coating as well as screening.

In an embodiment of the present disclosure, certain conductive ink such as paste ink or nano ink may be used as the conductive ink. However, when nano ink is used, calcination at low temperature is possible as a diameter of a nano particle is smaller. Therefore, when calcination at low temperature is required, it may be preferable to use conductive nano ink formed of nano particles of a few micrometers to tens of micrometers which can be calcined at relatively low temperature. Alternatively, the first circuit pattern 40 may be formed in a drawing method by using a conductive ink pen that does not require separate heat calcination.

In an embodiment, when the first circuit pattern 40 is formed on the stepped portion 13 or an inclined surface of the curved portion of the 3D metal board 10, various combinations of types of conductive ink and/or circuit pattern printing methods may be used. When ink of low viscosity is used for the stepped portion or the inclined surface, it is not easy to uniformly coat the surface of the stepped portion or inclined surface with ink. Therefore, it may be preferable to use nano ink of relatively high viscosity or conductive paste. In addition, in this case, a combination of drawing, spraying, and screening may be used. For example, a circuit pattern may be formed on the stepped portion or inclined surface by using a drawing ink pen, first, and then conductive ink may be coated over the circuit pattern by spraying or screening. In another example, the circuit pattern 40 may be formed by spraying or screening, and then conductive ink may be additionally coated over the circuit pattern 40 by drawing.

The method may further include a step of drying the conductive ink after forming the circuit pattern in at least one of spray coating and screening. The step of drying may be performed with the first mask 30 being attached as it is after the conductive ink is coated, or may be performed after the first mask 30 is removed after the conductive ink is coated.

As a method for drying the conductive ink, drying at room temperature, drying by light reaction, and heat drying may be used. Different drying methods may be performed according to types of the used conductive ink. For example, when drawing is performed along the circuit pattern with a conductive ink pen, the circuit pattern may be formed by drying at room temperature, or, when the conductive ink includes a photo-initiator which reacts to ultraviolet rays, the conductive ink may be dried by radiating ultraviolet rays. In addition, in the case of normal conductive ink, the conductive ink may be dried by using hot air, radiating light (for example, infrared rays or near infrared rays), or heating by using a convection oven.

After the first circuit pattern 40 is formed on the first insulation layer 20 as described above, a second insulation layer 50 may be formed on the first circuit pattern 40 as shown in step S30 of FIG. 3 and FIG. 5A.

The second insulation layer 50 may be formed to cover the entirety of the first insulation layer 20, or may be formed to cover some region of the first insulation layer 20. In addition, when the first circuit pattern 40 is required to be electrically connected with a circuit pattern to be formed thereon (for example, a “second circuit pattern” described hereinbelow) or a circuit element should be mounted on a certain region 41 of the first circuit pattern 40, the second insulation layer 40 may be formed on a region except for such regions 41.

An exemplary method for forming the second insulation layer 50 may include attaching a second mask (not shown) perforated in the shape of an insulation layer pattern to the first circuit pattern 40, and then coating insulating ink over the second mask according to the shape of the insulation layer pattern by drawing, screening, or spray coating.

The second mask may have the same or similar material as or to that of the first mask 30, and may be, for example, a metallic film or a polymer resin film. The second mask may be a single mask covering the entirety of the first circuit pattern 40, or may include a plurality of sub masks to cover different regions, respectively. When the second mask includes the plurality of sub masks, the plurality of sub masks may include a flat sub mask to cover a flat region of the 3D metal board 10 and a 3D sub mask to cover a stepped portion or a curved portion of the 3D metal board, similarly to the first mask 30 of FIG. 4C.

The insulating ink may be the same or similar insulating ink as or to that used for the first insulation layer 20. For example, the insulating ink may use PSR ink, but is not limited thereto, and may use a certain insulating liquid or an insulating material of a paste type, which is well known in the related art. In addition, the method may further include a step of drying (curing) the second insulation layer 50 by exposing to ultraviolet rays or heating according to a type of the insulating ink after forming the second insulation layer 50.

Next, referring to step S40 and FIG. 5B, a second conductive circuit pattern 60 is formed on the second insulation layer 50. In an embodiment, a third mask 30 (not shown) perforated in the shape of a conductive pattern may be attached to the second insulation layer 50, and then, by coating conductive ink over the third mask according to the shape of the conductive pattern by one of drawing, spray coating, and screening or a combination of two or more of these methods, the second circuit pattern 60 may be formed. A specific method for forming the second circuit pattern 60 or the conductive ink is the same as or similar to that of the first circuit pattern 40 described above, and thus a detailed description thereof is omitted.

In addition, the third mask used for forming the second circuit pattern may have the same or similar configuration as or to that of the first mask 30 described above. That is, the third mask 30 may include a plurality of sub masks to cover different regions of the surface of the 3D metal board, respectively, and the plurality of sub masks may include one or more flat sub mask to cover flat regions of the 3D metal board, and one or more 3D sub mask to cover stepped portions or curved portions of the 3D metal board.

After the second circuit pattern 60 is formed, a third insulation layer 70 may be formed on the second circuit pattern 60 as shown in step S50 and FIG. 5C. The third insulation layer 70 may be formed to cover the entirety of the surface of the metal board 10 or the entirety of the second insulation layer 50, but the third insulation layer 70 may be formed to cover the second circuit pattern 60 since the main purpose of forming the third insulation layer 70 is to protect the second circuit pattern 60. In addition, when a circuit element should be mounted on certain regions 61 of the first circuit pattern 40 or the second circuit pattern 60, the third insulation layer 70 may be formed on a region except for such regions 61.

An exemplary method for forming the third insulation layer 70 may include attaching a fourth mask (not shown) perforated in the shape of an insulation layer pattern to the second circuit pattern 60, and then coating insulating ink over the fourth mask according to the shape of the insulation layer pattern by drawing, screening, or spray coating. The insulating ink or printing method and the fourth mask are the same as or similar to those of the first insulation layer 20 or the second insulation layer 40, and thus a detailed description thereof is omitted.

After the third insulation layer 70 is formed, the circuit element 100 is mounted on one or more circuit element mounting regions as shown in step S60 and FIG. 5D. In an embodiment, the circuit element 100 may be mounted on a mounting region of the first circuit pattern 40 or the second circuit pattern 60 by welding, or step S60 may be omitted according to a specific embodiment.

Although the structure in which the two circuit patterns 40, 60 are stacked one on another is illustrated in the above-described embodiment by way of an example, a multilayered circuit pattern of three or more layers may be formed according to specific embodiments of the present disclosure.

When the multilayered circuit pattern is formed on the 3D metal board 10 according the present disclosure as described above, the following technical effects can be obtained.

First, in the present disclosure, the stepped portion or the inclined surface of the 3D metal board can be used as a circuit pattern region. In a related-art method, a circuit pattern is formed only on a flat board and a circuit element is attached. However, in the present disclosure, the stepped portion or the inclined surface of the 3D metal board can be used, and in particular, the circuit pattern can be formed on the support pole 15 as shown in FIG. 2B, and circuit elements such as various sensors can be installed. Therefore, the entire surface of the 3D metal board can be used as a circuit pattern forming region, such that a degree of integration of the circuit can be enhanced. In addition, an unnecessary space caused by installation of a PCB is removed, such that miniaturization of a device can be achieved.

Second, according to the present disclosure, the multilayered circuit pattern can be formed and the circuit element can be mounted on the 3D surface of the metal board in a comparatively simple method. A lithography method including a light exposure process and an etching process may be used as a normal processing method for forming an insulation layer or a circuit pattern on a general flat metal board or PCB, but this processing method is complicated and is not easy to apply to a side surface or an inclined surface of a 3D structure. However, in the present disclosure, insulating ink and conductive ink may be used for printing by drawing, spraying or screening, and may be dried (cured) at room temperature or relatively low temperature, or an insulation sheet may be used, and also, a metallic or resin film is attached and then is removed without using a separate mask layer forming process. Therefore, the multilayered circuit pattern can be formed in a simple method in comparison to the related-art method.

Third, since the circuit pattern is directly formed on the surface of the 3D metal board as described above, heat diffusion efficiency can be enhanced and miniaturization is possible. When the insulation layer and the circuit pattern are formed according to an embodiment of the present disclosure, one pair of insulation layers and one pair of circuit patterns may be formed to have thickness within tens of micrometers (for example, 30-50 micrometers), and accordingly, heat generated from the circuit element or circuit pattern can be effectively diffused through the surface of the 3D metal board although the circuit patterns are formed in a multilayered structure.

While the invention has been shown and described with reference to certain preferred embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present disclosure.

What is claimed is:

1. A method for forming a multilayered circuit pattern on a surface of a 3D metal board, the method comprising:
forming a first insulation layer on the surface of the 3D metal board;
forming a first conductive pattern on the first insulation layer;
forming a second insulation layer on the first conductive pattern except for a predetermined region;
forming a second conductive pattern on the second insulation layer; and
forming a third insulation layer on the second conductive pattern except for one or more circuit element mounting regions.

2. The method of claim 1, further comprising mounting a circuit element on the one or more circuit element mounting regions.

3. The method of claim 1, wherein the forming the first insulation layer comprises forming the first insulation layer by coating an insulating ink over the surface of the 3D metal board by screening, spray coating, or solution immersion, and curing, or by attaching an insulation sheet to the surface of the 3D metal board.

4. The method of claim 3, wherein the forming the first conductive pattern comprises:
attaching a first mask perforated in a shape of a conductive pattern onto the first insulation layer; and
coating a conductive ink over the first mask according to the shape of the conductive pattern by drawing, spray coating, or screening.

5. The method of claim 4, wherein the first mask is a metallic film or a polymer resin film.

6. The method of claim 5, wherein the first mask comprises a plurality of sub masks to cover different regions of the surface of the 3D metal board, respectively, and
wherein the plurality of sub masks comprise one or more flat sub masks to cover flat regions of the 3D metal board, and one or more 3D sub masks to cover stepped portions or curved portions of the 3D metal board.

7. The method of claim 4, wherein the forming the second insulation layer comprises
attaching a second mask perforated in a shape of an insulation layer pattern onto the first conductive pattern; and
coating an insulating ink over the second mask according to the shape of the insulation pattern shape by drawing, screening, or spray coating, and curing.

8. The method of claim 7, wherein the second mask comprises a plurality of sub masks to cover different regions of the surface of the 3D metal board, respectively, and
wherein the plurality of sub masks comprise one or more flat sub masks to cover flat regions of the 3D metal board, and one or more 3D sub masks to cover stepped portions or curved portions of the 3D metal board.

9. The method of claim 7, wherein the forming the second conductive pattern comprises:
attaching a third mask perforated in a shape of a conductive pattern onto the second insulation layer; and
coating a conductive ink over the third mask according to the shape of the conductive pattern by drawing, spray coating, or screening.

10. The method of claim 9, wherein the third mask comprises a plurality of sub masks to cover different regions of the surface of the 3D metal board, respectively, and
wherein the plurality of sub masks comprise one or more flat sub masks to cover flat regions of the 3D metal board, and one or more 3D sub masks to cover stepped portions or curved portions of the 3D metal board.

11. The method of claim 9, wherein the forming the third insulation layer comprises:
attaching a fourth mask perforated in a shape of an insulation layer pattern onto the second conductive pattern; and
coating an insulating ink over the fourth mask in the shape of the insulation layer pattern by drawing, screening, or spray coating, and curing.

12. The method of claim 11, wherein the fourth mask comprises a plurality of sub masks to cover different regions of the surface of the 3D metal board, respectively, and
wherein the plurality of sub masks comprise one or more flat sub masks to cover flat regions of the 3D metal board, and one or more 3D sub masks to cover stepped portions or curved portions of the 3D metal board.
